(19) United States
(12) Patent Application Publication
(10) Pub. No.: US 2026/0068568 A1
(43) Pub. Date: Mar. 5, 2026

(54) WAFER BONDING METHOD

(71) Applicant: Powerchip Semiconductor Manufacturing Corporation, Hsinchu (TW)

(72) Inventors: Chih Feng Sung, Hsinchu (TW); Chia-Hao Yu, Taichung City (TW); Yu-Lun Chang, Hsinchu (TW); Tz-Shiuan Lin, Hsinchu (TW); Ying-Che Sun, Hsinchu (TW); Yan Ting Lin, Hsinchu (TW); Chih-Hao Chuang, Hsinchu City (TW)

(73) Assignee: Powerchip Semiconductor Manufacturing Corporation, Hsinchu (TW)

(21) Appl. No.: 18/914,291

(22) Filed: Oct. 14, 2024

(30) Foreign Application Priority Data
Aug. 30, 2024 (TW) 113132896

(51) Int. Cl. H01L 21/306

(52) U.S. Cl. CPC H01L 21/30604

(57) ABSTRACT

A wafer bonding method includes: disposing a device wafer on a carrier wafer to form an interface between the device wafer and the carrier wafer and a back surface of the device wafer opposite to the interface; forming a step structure at an upper corner of the back surface of the device wafer, so that the back surface of the device wafer has a profile of an external portion being higher than an inner portion; and performing a thinning process with an etching solution to the inner portion of the back surface of the device wafer.

### CROSS-REFERENCE TO RELATED APPLICATION

This application claims the priority benefit of Taiwan application serial no. 113132896, filed on Aug. 30, 2024. The entirety of the above-mentioned patent application is hereby incorporated by reference herein and made a part of this specification.

### BACKGROUND

### Technical Field

The disclosure relates to a semiconductor manufacturing process, and in particular to a wafer bonding method.

### Description of Related Art

In the semiconductor packaging process, after wafer to wafer bonding, the wafer edge trimming process and the wafer thinning process are performed; in which in the wafer thinning process, a tool such as a grinding wheel is used to perform rapid and precise grinding on the back surface of the wafer, and then, an etching solution such as HNA is used to perform isotropic micro-etching on the surface of the wafer to remove the damaged layer caused by grinding and release the stress.

However, the above-mentioned etching solution usually causes undesirable erosion of the interface exposed at sidewalls of the two upper and lower wafers, a phenomenon commonly referred to as side etching, which causes the upper wafer to suffer damages such as undercutting at the bottom exposed at the sidewall thereof. At the same time, the erosion of the sidewall interface also causes the surface of the lower wafer close to the sidewall to be eroded, resulting in a sunken appearance at the interface exposed at the sidewalls of the upper and lower wafers; and the structure bears greater stress than the surrounding intact structure, leading to the occurrence of the Si edge chipping effect.

### SUMMARY

The disclosure provides a wafer bonding method to solve the above problem of Si edge chipping.

The disclosure proposes a wafer bonding method, including: disposing a device wafer on a carrier wafer to form an interface between the device wafer and the carrier wafer, and a back surface of the device wafer opposite to the interface; forming a step structure at an upper corner of the back surface of the device wafer, so that the back surface of the device wafer has a profile of an external portion being higher than an inner portion; and performing a thinning process with an etching solution to the inner portion of the back surface of the device wafer.

According to an embodiment of the disclosure, the method further includes a trimming process before forming the step structure, so that a sidewall of the device wafer and an upper sidewall of the carrier wafer are aligned.

According to an embodiment of the disclosure, the method further includes a grinding process before forming the step structure to thin the back surface of the device wafer.

According to an embodiment of the disclosure, the step structure is formed by a method of photolithographic etching.

According to an embodiment of the disclosure, the method of photolithographic etching includes: forming a protection structure on the upper corner of the back surface of the device wafer; performing etching back on the back surface of the device wafer; and removing the protection structure.

According to an embodiment of the disclosure, the protection structure is a photoresist.

According to an embodiment of the disclosure, the photoresist is a negative photoresist.

According to an embodiment of the disclosure, the etching back reduces a thickness of the device wafer by 10 microns to 20 microns.

According to an embodiment of the disclosure, the etching solution is an HNA etching solution.

According to an embodiment of the disclosure, the etching solution does not contact the interface between the device wafer and the carrier wafer.

Based on the above, in the wafer bonding method proposed by the disclosure, since the step structure having the external portion being higher than the inner portion is formed on the back surface of the device wafer, when the process is performed with the etching solution, the etching solution such as HNA can be concentrated on the inner portion of the back surface of the device wafer to react, so as to prevent the etching solution from overflowing the back surface of the device wafer and coming into contact with the interface of the device wafer and the carrier wafer, to prevent the interface of the device wafer and the carrier wafer from the occurrence of a sunken appearance, and thereby preventing the undercutting phenomenon of the device wafer and the occurrence of Si edge chipping effect.

If there is excessive etching solution and the solution overflows the back surface of the device wafer, since there is the step structure having the external portion being higher than the inner portion, the etching solution overflows downward at a non-vertical angle, which reduces the chance of the interface of the device wafer and the carrier wafer coming into contact with the etching solution, and also prevents the occurrence of the sunken appearance at the interface of the device wafer and the carrier wafer due to erosion by the etching solution, thereby the chance of undercutting the device wafer and the occurrence of the Si edge chipping effect is reduced.

In order to make the above-mentioned features and advantages of the disclosure more comprehensible, embodiments are given below and described in detail with reference to the accompanying drawings.

### BRIEF DESCRIPTION OF THE DRAWINGS

FIG. 1 to FIG. 7 are cross-sectional views of a wafer bonding process according to some embodiments of the disclosure.

### DESCRIPTION OF THE EMBODIMENTS

Examples are listed below and described in detail with reference to the drawings. However, the provided examples are not intended to limit the scope of the disclosure. To facilitate understanding, the same components will be identified with the same reference numerals in the following description. In addition, the drawings are for illustrative purposes only and are not drawn to original size. In fact, the dimensions of the various features may be arbitrarily increased or reduced for clarity of discussion.

In addition, for ease of description, spatially relative terms such as “upper”, “lower”, and similar terms are used herein to describe the relative relationship between one component and another component as shown in the drawings. In addition to the orientation depicted in the drawings, the spatially relative terms are intended to encompass different orientations of the components in space, allowing for interpretations such as rotations of 90 degrees or other orientations, for example.

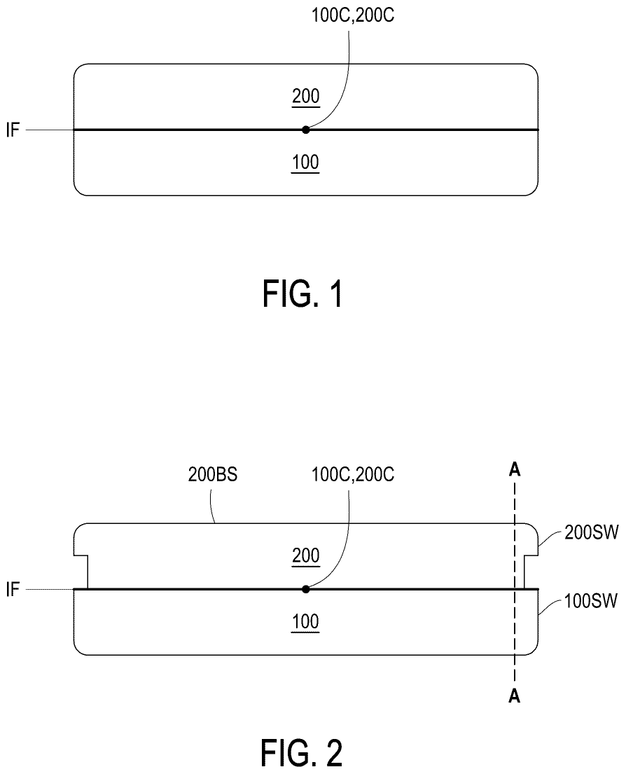

First, as shown in FIG. 1, through conventional methods or various methods developed in the future, a device wafer 200 may be disposed on a carrier wafer 100 to form an interface IF of the device wafer 200 and the carrier wafer 100, and a back surface 200BS opposite to the interface IF of the device wafer 200; in some embodiments, the carrier wafer 100 and the device wafer 200 have an overall circular shape (not shown); in some embodiments, the carrier wafer 100 and the device wafer 200 may be various semiconductor components, and may each include various semiconductor materials; in some embodiments, the carrier wafer 100 and the device wafer 200 may have the same or similar size, or may have different sizes, such as the smaller device wafer 200 located on the larger carrier wafer 100; in some embodiments, a center 200C of the device wafer 200 may be directly overlaid on a center 100C of the carrier wafer 100, so that the carrier wafer 100 and the device wafer 200 are aligned with each other, as shown in FIG. 1, but the disclosure is not limited thereto.

Next, as shown in FIG. 2, when/after disposing the device wafer 200 on the carrier wafer 100 as shown in FIG. 1, the edge of the device wafer 200 is usually uneven, and thus the wafer edge trimming process needs to be performed on sidewalls 200SW of the device wafer 200. For example, conventional methods or various methods developed in the future such as infrared (IR) alignment, stealth laser equipment, blade trimming, and grinding may be used to perform the wafer edge trimming process.

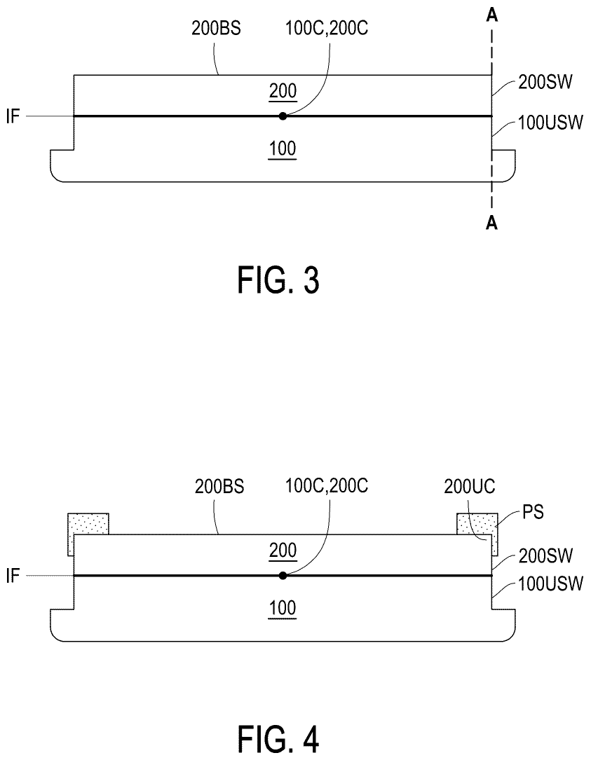

Please refer to FIG. 2 together with FIG. 3. The wafer edge trimming process is used to trim the sidewall 200SW of the device wafer 200 and an upper sidewall 100USW of the carrier wafer 100, so that the sidewall 200SW of the device wafer 200 and the upper sidewall 100USW of the carrier wafer 100 are aligned with a dashed line A as shown in FIG. 3.

Next, a thinning processing is performed on the back surface 200BS of the device wafer 200. The thinning processing usually includes the following two processes. First, a grinding tool such as a grinding wheel is used to grind the back surface 200BS of the device wafer 200. Then, an etching solution such as HNA is used to micro-etch the back surface 200BS of the device wafer 200 to remove the damaged layer caused by grinding and release the stress.

Please still refer to FIG. 2 and FIG. 3. After the wafer edge trimming process, grinding is performed on the back surface 200BS of the device wafer 200; in addition, the operation may also be to perform grinding on the back surface 200BS of the device wafer 200 first, and then to perform the wafer edge trimming process on the device wafer 200 and carrier wafer 100.

In some embodiments, the back surface 200BS of the device wafer 200 is ground away to a thickness of approximately 10 microns to 20 microns, but the actual removal amount may be selected according to the requirements of the process and is not limited to the removal amount disclosed above.

Next, before performing the second process of thinning the back surface 200BS of the device wafer 200, that is, before performing micro-etching with the etching solution on the back surface 200BS of the device wafer 200, the following process is added.

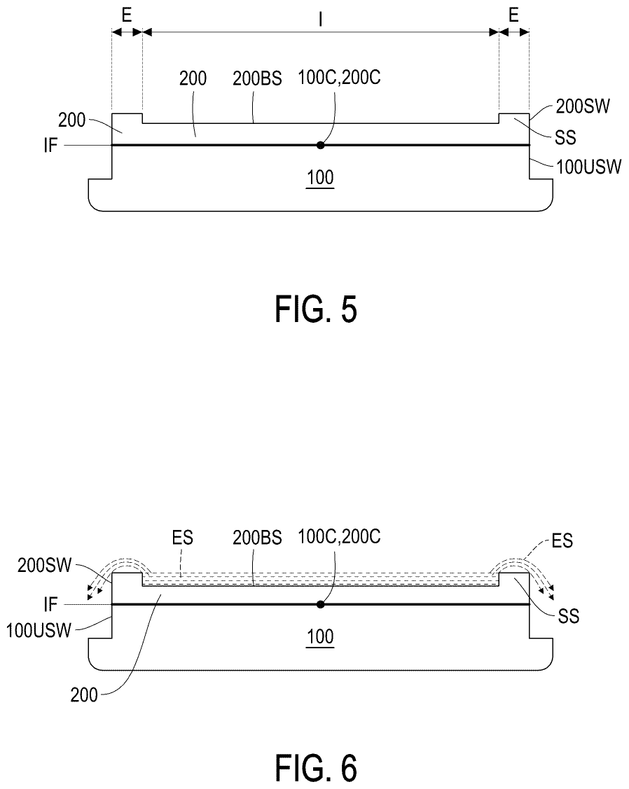

Please refer to FIG. 5 in advance. Various methods in the semiconductor manufacturing process may be used to form a step structure SS at an upper corner 200UC of the back surface 200BS of the device wafer 200, and the step structure SS causes the back surface 200BS of the device wafer 200 to have a profile of an external portion E being higher than an inner portion I.

For example, photolithographic etching may be used to form the step structure SS.

In some embodiments, referring to FIG. 4, a protection structure PS may be formed at the upper corner 200UC of the back surface 200BS of the device wafer 200. For example, the protection structure PS may be formed with various photoresists commonly used in semiconductor manufacturing processes; since the resolution of the negative photoresist is quite sufficient for forming the protection structure PS, in some embodiments, the protection structure PS may be formed by using the negative photoresist that is more economical than a positive photoresist. Certainly, the disclosure does not exclude the use of the positive photoresist. Then, etching back is performed on the back surface 200BS of the device wafer 200, and a thickness of approximately 10 microns to approximately 20 microns is removed from the inner portion I of the back surface 200BS of the device wafer 200 that is not covered by the protection structure PS; after the protection structure PS is removed, the step structure SS having the external portion E thereof higher than the inner portion I thereof is formed at the upper corner 200UC of the back surface 200BS of the device wafer 200.

Next, the second process of thinning the back surface 200BS of the device wafer 200 may be performed. As shown in FIG. 6, an etching solution ES is used to perform the micro-etching process on the back surface 200BS of the device wafer 200 to remove the damaged layer caused by the first process of the thinning processing, grinding, and release the stress.

In some embodiments, the etching solution ES may include HNA etching solution, but is not limited thereto; the HNA etching solution contains hydrofluoric acid (HF), nitric acid (HNO₃), and acetic acid (CH₃COOH).

As shown in FIG. 6, in the disclosure, since the step structure SS having the external portion E being higher than the inner portion I is formed on the back surface 200BS of the device wafer 200, when the process is performed with the etching solution ES, the etching solution ES such as HNA can be concentrated on the inner portion I of the back surface 200BS of the device wafer 200 to react, so as to prevent the etching solution ES from overflowing the back surface 200BS of the device wafer 200 and coming into contact with the interface IF of the device wafer 200 and the carrier wafer 100, to prevent the interface IF of the device wafer 200 and the carrier wafer 100 from the occurrence of a sunken appearance, and thereby preventing the undercutting phenomenon of the device wafer 200 and the occurrence of Si edge chipping effect.

Furthermore, as shown in FIG. 6, if there is excessive etching solution ES and the solution overflows the back surface 200BS of the device wafer 200, since there is the step structure SS having the external portion E being higher than the inner portion I, the etching solution ES overflows downward at a non-vertical angle, which reduces the chance of the interface IF of the device wafer 200 and the carrier wafer 100 coming into contact with the etching solution ES, and also prevents the occurrence of the sunken appearance at the interface IF of the device wafer 200 and the carrier wafer 100 due to erosion by the etching solution ES, thereby the chance of undercutting the device wafer 200 and the occurrence of the Si edge chipping effect is reduced.

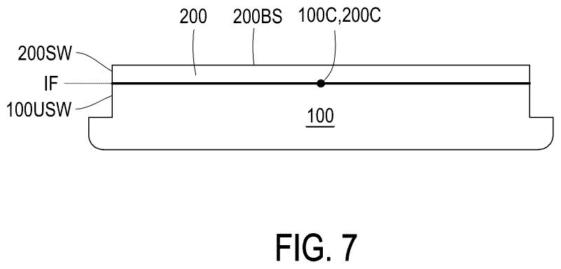

Then, the thickness of the external portion E of the back surface 200BS of the device wafer 200 may be reduced to the same thickness as the inner portion I by various photolithographic etching methods, as shown in FIG. 7, so that the back surface 200BS of the device wafer 200 is a flat surface, and without the Si edge chipping effect.

In summary, in the wafer bonding method of the embodiments, since the back surface of the device wafer has formed the step structure having the external portion higher than the inner portion, when the process is performed with the etching solution, the etching solution such as HNA can be concentrated on the inner portion of the back surface of the device wafer to react, so as to prevent the etching solution from overflowing the back surface of the device wafer and contacting the interface of the device wafer and the carrier wafer, to prevent the interface of the device wafer and the carrier wafer from the occurrence of the sunken appearance, and thereby preventing the undercutting phenomenon of the device wafer and the occurrence of Si edge chipping effect.

If there is excessive etching solution and the solution overflows the back surface of the device wafer, since there is the step structure having the external portion being higher than the inner portion, the etching solution overflows downward at a non-vertical angle, which reduces the chance of the interface of the device wafer and the carrier wafer coming into contact with the etching solution, and also prevents the occurrence of the sunken appearance at the interface of the device wafer and the carrier wafer due to erosion by the etching solution ES, thereby the chance of undercutting the device wafer and the occurrence of the Si edge chipping effect is reduced.

Although the disclosure has been disclosed above through embodiments, the embodiments are not intended to limit the disclosure. Persons with ordinary knowledge in the relevant technical field may make some changes and modifications without departing from the spirit and scope of the disclosure. Therefore, the protection scope of the disclosure shall be determined by the appended claims.

What is claimed is:

1. A wafer bonding method, comprising:
disposing a device wafer on a carrier wafer to form an interface between the device wafer and the carrier wafer, and a back surface of the device wafer opposite to the interface;
forming a step structure at an upper corner of the back surface of the device wafer, so that the back surface of the device wafer has a profile of an external portion being higher than an inner portion; and
performing a thinning process with an etching solution to the inner portion of the back surface of the device wafer.

2. The wafer bonding method as claimed in claim 1, wherein the method further comprises a trimming process before forming the step structure, so that a sidewall of the device wafer and an upper sidewall of the carrier wafer are aligned.

3. The wafer bonding method as claimed in claim 1, wherein the method further comprises a grinding process before forming the step structure to thin the back surface of the device wafer.

4. The wafer bonding method as claimed in claim 1, wherein the step structure is formed by a method of photolithographic etching.

5. The wafer bonding method as claimed in claim 4, wherein the method of photolithographic etching comprises:
forming a protection structure on the upper corner of the back surface of the device wafer;
performing etching back on the back surface of the device wafer; and
removing the protection structure.

6. The wafer bonding method as claimed in claim 5, wherein the protection structure is a photoresist.

7. The wafer bonding method as claimed in claim 6, wherein the photoresist is a negative photoresist.

8. The wafer bonding method as claimed in claim 5, wherein the etching back reduces a thickness of the device wafer by 10 microns to 20 microns.

9. The wafer bonding method as claimed in claim 1, wherein the etching solution is an HNA etching solution.

10. The wafer bonding method as claimed in claim 1, wherein the etching solution does not contact the interface between the device wafer and the carrier wafer.
